(19) United States
(12) Patent Application Publication
(10) Pub. No.: US 2008/0286984 A1
(43) Pub. Date: Nov. 20, 2008

(54) SILICON-RICH LOW-HYDROGEN CONTENT SILICON NITRIDE FILM

(76) Inventors: Jason B. Taylor, Alameda, CA (US); Chiliang Chen, Sunnyvale, CA (US)

Correspondence Address: MACPHERSON KWOK CHEN & HEID LLP, 2033 GATEWAY PLACE, SUITE 400, SAN JOSE, CA, 95110, US

(21) Appl. No.: 11/748,349

(22) Filed: May 14, 2007

(51) Int. Cl. H01L 21/31

(52) U.S. Cl. 438/792; 257/E21.293

(57) ABSTRACT

In one embodiment, a method for forming a silicon nitride film is provided. The method includes providing a plasma-enhanced chemical vapor deposition (PECVD) reactor with a semiconductor substrate therein; flowing a gas mixture consisting of silane and nitrogen into the PECVD reactor; and forming a plasma in the PECVD reactor, whereby the silicon nitride film is deposited on the semiconductor substrate.

### BACKGROUND

1. Field of Disclosure

The present invention relates to the fabrication of integrated circuit structures, and more particularly, this invention relates to a plasma-enhanced chemical vapor deposition of a silicon nitride layer in an integrated circuit device.

2. Description of Related Art

During the manufacture of miniaturized circuit devices, intermediate (e.g., hard masks) and/or final structures (e.g., passivation layers) are often formed with combinations of patterned materials composed of oxides and nitrides of silicon disposed adjacent to one another. The oxides and nitrides may be further disposed adjacent to monocrystalline, polycrystalline, or other forms of silicon. It is often times desirable to strip away or otherwise etch/pattern the silicon nitride (“nitride”) material while not significantly etching into adjacent silicon or silicon oxide (“oxide”).

Thus, an improved silicon nitride film that may be readily patterned and has a higher throughput while maintaining sufficient etch rate and selectivity is desirable for improved scaling of circuit structures. Furthermore, providing a hard mask material that is compatible with low-temperature semiconductor processing is desirable.

### SUMMARY

The present invention provides a silicon-rich low-hydrogen content PECVD nitride layer that is selective to oxide and may be used as an advantageous hard mask or passivation layer.

In accordance with one embodiment of the present invention, a method of forming a nitride layer includes providing a plasma-enhanced chemical vapor deposition (PECVD) reactor with a semiconductor substrate therein, flowing a gas mixture consisting of silane and nitrogen into the PECVD reactor, and forming a plasma in the PECVD reactor, whereby a silicon nitride film is deposited on the semiconductor substrate.

In accordance with another embodiment of the present invention, another method of forming a nitride layer is disclosed, including the steps as noted above, wherein the silicon nitride film has a stoichiometric composition of SiₓN_{y}H_{z}, wherein x>y>z.

The scope of the invention is defined by the claims, which are incorporated into this section by reference. A more complete understanding of embodiments of the present invention will be afforded to those skilled in the art, as well as a realization of additional advantages thereof, by a consideration of the following detailed description of one or more embodiments. Reference will be made to the appended sheets of drawings that will first be described briefly.

### BRIEF DESCRIPTION OF THE DRAWINGS

FIGS. 1A through 1D illustrate sectional views of the formation of an IC structure, to which a nitride layer of the present invention may be applied in accordance with an embodiment of the present invention.

FIGS. 2A and 2B show a top down view and a side view, respectively, of an apparatus in which the present invention may be practiced in accordance with an embodiment of the present invention.

FIG. 3 shows the elemental composition of a silicon nitride film in accordance with an embodiment of the present invention.

FIG. 4 shows the concentration of N—H bonds, Si—H bonds, and total H atoms of a silicon nitride film in accordance with an embodiment of the present invention.

FIG. 5 shows a comparison of N—H bonds, Si—H bonds, and Si—N bonds in a silicon nitride film in accordance with an embodiment of the present invention and a standard silicon nitride film.

Embodiments of the present invention and their advantages are best understood by referring to the detailed description that follows. It should be appreciated that like reference numerals are used to identify like elements illustrated in one or more of the figures. It should also be appreciated that the figures may not be necessarily drawn to scale.

### DETAILED DESCRIPTION

In one embodiment, the present invention includes a method for depositing a silicon-rich low-hydrogen content silicon nitride (“nitride”) film using an ammonia-free plasma process in a plasma enhanced chemical vapor deposition (PECVD) reactor. The method lowers the concentration of N—H bonds and total hydrogen by, among other things, supplying only silane and nitrogen to the plasma reactor and not including ammonia in the plasma precursor gas. This reduces the amount of hydrogen available to the reaction. The method also dramatically increases the amount of nitrogen provided to the PECVD reactor while also reducing the amount of silane provided to the PECVD reactor as compared to process parameters for forming conventional nitride layers.

For instance, a conventional PECVD silicon nitride film may be produced in a PECVD process having a silane (SiH₄) flow rate of about 500 sccm, and a gas flow ratio of 1 SiH₄:8 NH₃:3 N₂. In one example, the reactor used may be a CONCEPT ONE dual-frequency parallel plate PECVD reactor available from Novellus Systems, Inc. of San Jose, Calif. Additional detail concerning the CONCEPT ONE reactor is provided below.

Note that, in this conventional process, the flow rate of the nitrogen is less than the flow rate of the ammonia. Also note that, as is expected for silicon nitride films produced by PECVD, the stoichiometry of the PECVD silicon nitride is not a match to pure silicon nitride (Si₃N₄). This is apparent, for instance, from the relatively lower amount of nitrogen in the film and the presence of hydrogen in the film. The amount of nitrogen in the conventional film is less than the amount of silicon. The concentration of Si—H bonds in a conventional nitride film is about 1e22 bonds/cm³.

A process for producing a silicon-rich, low-hydrogen content PECVD silicon nitride film in accordance with the present invention uses a lower silane flow rate than in the conventional process but a much greater flow rate of nitrogen. For instance, a silane flow rate of 100 sccm may be used with gas flow ratios of 1 SiH₄:45 N₂. In this embodiment, the nitrogen flow rate is significantly increased so as to constitute the overwhelming portion of the gas flow.

A process of the present invention also does not use ammonia as a precursor gas nor high frequency RF power when generating the plasma. Accordingly, in one embodiment of the present invention, the deposition process is free of ammonia and high frequency RF.

In one example, the silicon-rich, low-hydrogen content, and ammonia-free PECVD silicon nitride film so produced has a stoichiometry of SiₓN_{y}H_{z}, where x is about 50, y is about 37, and z is about 13. The nitride film also has a N—H bond concentration of about 4e21 bonds/cm³, which is significantly lower than in the conventional opaque PECVD silicon nitride film which has a N—H bond concentration of about 1.4e22 bonds/cm³. Further, the film is hydrogen and nitrogen poor as compared to the conventional PECVD silicon nitride film mentioned above.

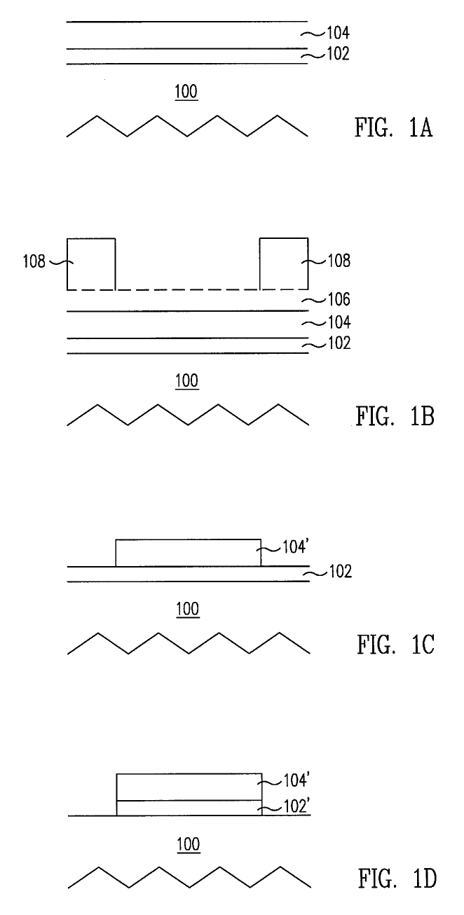

Referring now to FIGS. 1A through 1D, sectional views are illustrated of the formation of an IC structure, to which a nitride layer of the present invention may be applied in accordance with an embodiment of the present invention. As noted above, the nitride layer has a low hydrogen content and is deposited via PECVD using a gas mixture without ammonia (NH₃) but including silane (SiH₄) and nitrogen (N₂). It should be understood that the present invention is not limited to this structure or other particular integrated circuit embodiments discussed herein.

In FIG. 1A, a silicon nitride layer 104 is formed over a silicon oxide layer 102, which is formed over the surface of a substrate 100 in accordance with an embodiment of the present invention. The present invention includes forming nitride layer 104 of a silicon-rich, low-hydrogen content PECVD silicon nitride. In one example, nitride layer 104, with no intent to limit the invention thereby, may have a thickness between about 1,000 angstroms and about 3,000 angstroms.

Substrate 100 may be formed of a general semiconductor material and may be doped by conventional means with dopants at different dosage and energy levels to form wells. Substrate 100 may be a wafer formed from a single crystalline silicon material, or it may also be comprised of other materials, for example, an epitaxial material, a polycrystalline semiconductor material, or other suitable material. It is noted that substrate 100 can further include additional layers, structures, and/or devices.

Oxide layer 102 may be formed using standard techniques, and in one example, with no intent to limit the invention thereby, may have a thickness between about 4,000 angstroms and about 9,000 angstroms.

In FIG. 1B, an anti-reflective coating (ARC) layer 106 and photoresist pattern 108 are formed over nitride layer 104 using standard techniques in accordance with an embodiment of the present invention. Those skilled in the art of depositing ARC material will understand that different ARC formulations may be used and that the selected ARC fluid may be adapted for providing either a substantially planar top surface or a nonplanar top surface, where the formed ARC layer conformingly follows the contour of the substrate surface. When ARC is conventionally used for providing an anti-reflective function in a photolithographic step, the amount of material deposited at the center of the wafer is usually set to be either a fairly large amount for providing a planarized top surface for the hardened ARC layer; or the amount of material deposited at the center of the wafer is set to be a relatively small amount so that a very thin and very conforming layer of hardened ARC will coat the underlying substrate surface. After this, a coating of photoresist material (PR) is deposited on the ARC 106 and patterned using standard photoresist coating, exposure, and development processes known in the conventional lithography technology.

In FIG. 1C, nitride layer 104 is etched through photoresist pattern 108 to form nitride layer 104′ over oxide layer 102 in accordance with an embodiment of the present invention. Remaining photoresist 108 and ARC 106 may be removed. Nitride layer 104′ may be used as a hard mask, a spacer, a passivation layer, or for a variety of other functions. In one example, nitride layer 104 may be etched using a standard CF₄ and CHF₃ etch using a SuperE etcher available from Applied Materials, Inc. of Santa Clara, Calif. Because of the ability of dry etch processes to etch anisotropically (in comparison to wet etch processes, which etch isotropically), dry etching may be used in one example. There are three types of dry etch processes: those that have a physical basis (e.g., ion beam milling), those that have a chemical basis (e.g., non-plasma assisted chemical etching), and those that combine both physical and chemical mechanisms (e.g., reactive ion etching and some types of plasma-assisted etching). Primarily physical dry etch methods may not exhibit sufficient selectivity of the superjacent layer over the underlying layer causing punchthrough of the underlying layer. On the other hand, primarily chemical processes typically etch isotropically and therefore do not form vertical sidewalls. Consequently, chemically enhanced ion etching processes that combine the two mechanisms are preferred. Accordingly, in one embodiment, the method of the present invention utilizes a dry etch involving simultaneous ion bombardment and polymerizing chemistry to etch the nitride layer. Various etching means and methods may be used, in one example being described in commonly-owned U.S. Pat. No. 6,846,730, which is incorporated by reference herein for all purposes. It is noted that the etch process should be timely halted by, for example, using an appropriate rinse (e.g., deionized water) once sufficient time has passed.

Then, as shown in FIG. 1D, oxide layer 102 is etched using nitride layer 104′ as a mask to form oxide layer 102′ over substrate 100 in accordance with an embodiment of the present invention. A ratio or selectivity of oxide etch rate/nitride etch rate greater than 10 is achievable in one example.

Subsequently, nitride layer 104′ may be removed, for example by a liquid strip process using an appropriate acid, an ashing process, and/or a planarization process, such as chemical mechanical polish (CMP). Advantageously, because silicon nitride which is thermally grown tends to have relatively high density while CVD-deposited nitrides tend to be less dense, the less dense nitride of the present invention will etch more quickly than a thermally-grown nitride. Also, the CVD-deposited nitrides can be formed more quickly and at lower cost.

The invention can be implemented in any applicable plasma enhanced chemical vapor deposition (PECVD) system. A typical plasma reactor includes a plasma processing chamber with a chamber electrode powered by a first power source, such as a radio frequency (RF) power source. Typically, a gas port is provided within the chamber and is arranged for releasing gaseous source materials, e.g., the etchant source gases, into the RF-induced plasma region. The gaseous source materials may be released from ports built into the walls of the chamber itself or through a shower head. A wafer may be introduced into the chamber and disposed on a chuck or pedestal, which acts as a bottom electrode and can be biased by a second power source. The chuck may be, in one example, an electrostatic chuck, which secures a substrate to the chuck's surface by electrostatic force. By applying power to the top chamber electrode, a plasma may be created within the chamber by causing the molecules of one or more of the inflowing gases to disassociate into respective submolecular constituents (e.g., free radicals or free ions). Power is applied to the electrostatic chuck or pedestal to attract ionized molecules in the plasma toward the wafer surface for sputter etching. An exhaust port is typically disposed on one side of the chamber and coupled to a pump typically located outside of the chamber. The pump maintains the desired pressure inside the chamber.

By way of a further example, it is understood that the configuring of a deposition tool for deposition of a nitride film or an etchback tool for etching of a nitride film may be automated. A deposition tool or an etchback tool or process in accordance with the present disclosure may therefore include the use of a computer to carry out automatic processing of the wafer, such as venting of the chamber, transfer of wafers to and from loading modules, and delivery of process gas and electrode power, and/or automatic setting of process parameters, such as of gas compositions and bias power. A computer-readable medium or another form of a software product or machine-instructing means (including but not limited to, a hard disk, a compact disk, a flash memory stick, a downloading of manufactured instructing signals over a network and/or like software products) may be used for instructing an instructable machine (e.g., a plasma deposition or etch tool) to carry out such automated activities. As such, it is within the scope of the disclosure to have an instructable machine carry out, and/or to provide a software product adapted for causing an instructable plasma deposition or etch machine to carry out the disclosed deposition or etch steps.

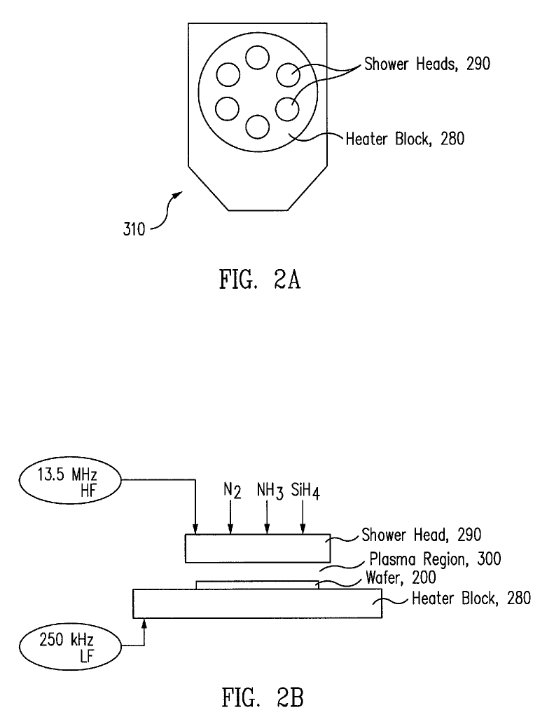

As mentioned, the process can be implemented using a CONCEPT ONE dual frequency parallel plate plasma reactor in one example. Such a reactor 310 is shown schematically in FIGS. 2A and 2B. The apparatus includes a heater block 280 that supports six semiconductor substrates 200 in a reactor chamber in one example. The reactant gases enter the reaction chamber through one of six individual showerheads 290, each suspended above a corresponding semiconductor substrate 200. The reactant gases flow through the showerhead holes into the plasma region 300 and across the face of the semiconductor substrate 200. A high frequency (13.56 MHz) RF power source is coupled to the showerhead 290, and a low frequency (250 KHz) RF power source is coupled to the heater block 280.

The semiconductor substrate 200 is loaded into the chamber 310. The recommended operating temperature of the chamber is 400 degrees centigrade. Then, the chamber is evacuated and the gas inlet and other outlet lines are purged to clean the system of any unwanted contaminants.

The reactant gases including silane and nitrogen, in one example, are introduced into the reactor chamber. Conventional precursor gases have included ammonia but is not included in the present invention. In one example, a silane flow rate of about 100 scam may be used, with gas flow ratios of about 1 SiH₄:45 N₂. The relatively low flow rate of the silane gas, along with the relatively high flow rate of nitrogen, and the lack of ammonia, reduces the amount of hydrogen and nitrogen in the film.

The RF power is applied, and induces an oscillatory field in the gas, which accelerates any charged species along the field lines. Thereby, the charged species collide with the neutral species, ionizing the neutral species until a plasma comprising ionized species is formed in the reactor chamber above the substrate 200. The gas precursors decompose in the plasma, and react together on the semiconductor substrate 200 to deposit silicon-rich, low-hydrogen content silicon nitride film 104.

The ranges of RF power applied to the apparatus were between 0.1 kW and 0.5 kW for the low frequency power supply. RF power was not applied for the high frequency power supply in one embodiment of the present invention.

The reactor pressure was held to about 2.0 torr compared to the conventional 2.6 torr. The reactor pressure was high enough to maintain a stable plasma. Increasing the pressure beyond this range increases the mass flow rate required of the precursor gases. Lower pressures may reduce the deposition rate of the film.

In one embodiment, the wafer is heated to a temperature of about 400 degrees centigrade. Lower temperatures may reduce the deposition rate and increase the pinhole defect density in the resulting film. Increased temperatures tend to be avoided to reduce the thermal budget of the films and transistor structures.

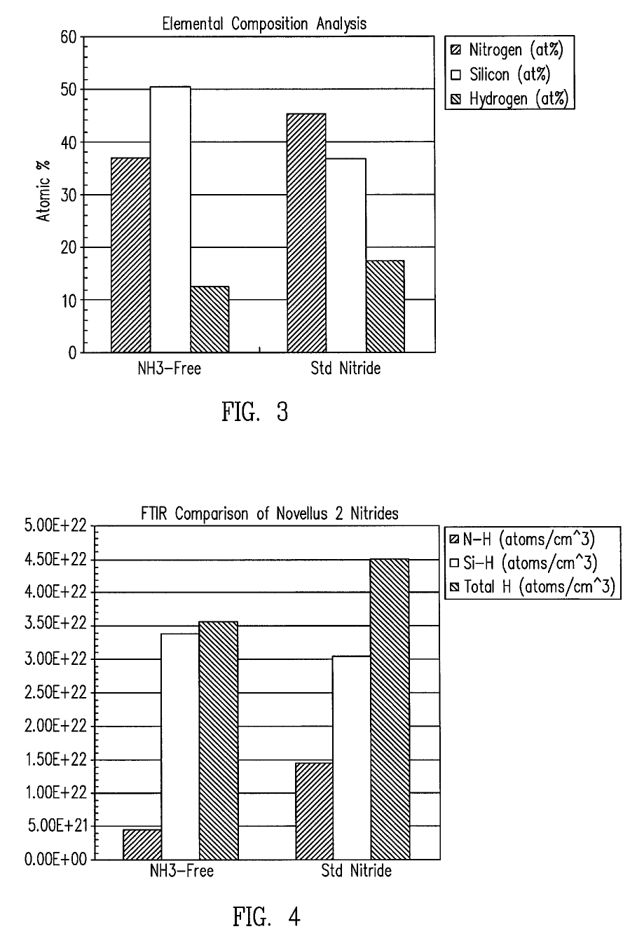

Referring now to FIGS. 3 through 5 in conjunction with Tables 1 and 2 below, process parameters and nitride attributes in accordance with the present invention as compared to process parameters and nitride attributes of conventional nitride layers are tabulated in Tables 1 and 2, with the nitride attributes being graphically shown in FIGS. 3 through 5.

Table 1 below tabulates some process parameters for forming a nitride film according to an embodiment of the present invention. The nitride film is formed in a PECVD chamber using between about 4000 sccm and about 5000 sccm of nitrogen, in one example being about 4500 sccm of nitrogen, and between about 50 sccm and about 200 sccm of silane, in one example being about 100 sccm of silane. No ammonia is used in one example. Other process parameters in accordance with the present invention include applying a low frequency RF of about 300 W at a process pressure of about 2 Torr and a process temperature of about 400 centigrade. No high frequency RF is applied in one example. In contrast, a conventional nitride film is formed in a PECVD chamber using about 1600 sccm of nitrogen, about 500 sccm of silane, and about 4000 sccm of ammonia. Other conventional process parameters include applying a high frequency RF of about 570 W and a low frequency RF of about 430 W at a process pressure of about 2.6 Torr and a process temperature of about 400 centigrade.

In accordance with the present invention, process parameters may vary, depending, for instance, on the reactor configuration and desired throughput and film properties. Suffice to say that, within the present invention, the flow rate of nitrogen is significantly greater than the flow rate of the silane, such that the silicon-rich, low-hydrogen content PECVD silicon nitride film so produced has a stoichiometry of SiₓN_{y}H_{z}, where x>y>z (e.g., x is about 50, y is about 37, and z is about 13). Ammonia is not supplied to the PECVD reactor as compared to the process for making the conventional silicon nitride film.

TABLE 1

| Process | New | Conventional |
|---|---|---|
| Parameters | Nitride Film | Nitride Film |
| Nitrogen (N2) flow (sccm) | 4000–5000 | 1600 |
| Silane (SiH4) flow (sccm) | 50–200 | 500 |
| Ammonia (NH3) flow (sccm) | 0 | 4000 |
| High Frequency RF (W) | 0 | 570 |
| Low Frequency RF (W) | 300 | 430 |
| Pressure (Torr) | 2.0 | 2.6 |
| Temperature (° C.) | 400 | 400 |

Table 2 below tabulates data describing nitride layer attributes of the present invention in one embodiment, and FIGS. 3 through 5 graphically illustrate this data.

TABLE 2

| Nitride Film | New | Conventional |
|---|---|---|
| Attributes | Nitride Film | Nitride Film |
| N (atomic %) | 37.1 | 45.4 |
| Si (atomic %) | 50.3 | 37.1 |
| H (atomic %) | 12.6 | 17.5 |
| Density (atoms/cc) | 9.72e22 | 1.09e23 |
| N—H (bonds/cm\hat{ }3) | 4.44e21 | 1.47e22 |
| Si—H (bonds/cm\hat{ }3) | 3.40e22 | 3.05e22 |
| Total H (atoms/cm\hat{ }3) | 3.58e22 | 4.52e22 |
| Si—H:N—H Ratio | 7.07 | 2.07 |
| Index of Refractivity | 2.70 | 2.04 |

FIG. 3 shows the elemental composition of a silicon nitride film of the present invention as compared to a conventional silicon nitride film. In one example, the nitride film of the present invention has a nitrogen composition, silicon composition, and hydrogen composition of about 37.1 atomic percent, about 50.3 atomic percent, and about 12.6 atomic percent, respectively, as compared to the conventional nitride film having a nitrogen composition, silicon composition, and hydrogen composition of about 45.4 atomic percent, 37.1 atomic percent, and 17.5 atomic percent, respectively. Thus, the nitride of the present invention provides for relatively less nitrogen content, greater silicon content, and less hydrogen content as compared to the conventional nitride.

FIG. 4 shows N—H bond concentration, Si—H bond concentration, and total H concentration, of the nitride film of the present invention compared to a conventional nitride film as measured using Fourier Transform Infrared (FTIR) analysis. The concentration of Si—H bonds in this regime is about 3E22 bonds/cm̂3 for the conventional silicon nitride film to about 3.4E22 bonds/cm̂3 for the new silicon-rich low-hydrogen content silicon nitride film formed in accordance with the present invention. Thus, the nitride of the present invention provides for relatively less N—H bond concentration, greater Si—H bond concentration, and less total H concentration as compared to the conventional nitride.

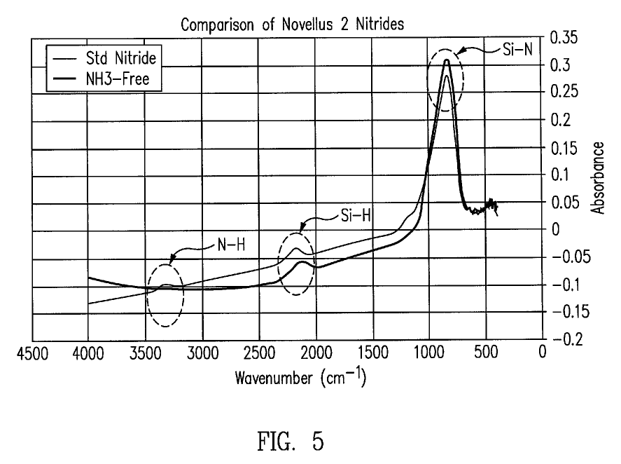

FIG. 5 shows a comparison of N—H bonds, Si—H bonds, and Si—N bonds between a silicon nitride film in accordance with an embodiment of the present invention and a standard or conventional silicon nitride film. The nitride of the present invention has more Si—H bonds and Si—N bonds compared to a conventional nitride film, corresponding to the graph of FIG. 4. The N—H absorption peak was below the detection limits of FTIR from this graph.

The present disclosure is to be taken as illustrative rather than as limiting the scope, nature, or spirit of the subject matter claimed below. Numerous modifications and variations will become apparent to those skilled in the art after studying the disclosure, including use of equivalent functional and/or structural substitutes for elements described herein, use of equivalent functional couplings for couplings described herein, and/or use of equivalent functional steps for steps described herein. For instance, the invention is not limited to any particular deposition tool, but can be applied to any plasma enhanced chemical vapor deposition apparatus. Furthermore, process parameters can be varied. Such variations are to be considered within the scope of what is contemplated here. Moreover, if plural examples are given for specific means, or steps, and extrapolation between and/or beyond such given examples is obvious in view of the present disclosure, then the disclosure is to be deemed as effectively disclosing and thus covering at least such extrapolations. Given the above disclosure of general concepts and specific embodiments, the scope of protection sought is to be defined by the claims appended hereto.

What is claimed is:

1. A method, comprising:
providing a plasma-enhanced chemical vapor deposition (PECVD) reactor with a semiconductor substrate therein;
flowing a gas mixture consisting of silane and nitrogen into the PECVD reactor; and
forming a plasma in the PECVD reactor, whereby a silicon nitride film is deposited on the semiconductor substrate.

2. The method of claim 1, wherein a flowrate of silane is about 100 sccm.

3. The method of claim 1, wherein a flowrate of nitrogen is about 4,500 sccm.

4. The method of claim 1, wherein a flowrate ratio of silane to nitrogen is about 1:45.

5. The method of claim 1, wherein forming the plasma comprises applying a low frequency RF power of about 300 W to the plasma reactor.

6. The method of claim 1, wherein forming the plasma comprises maintaining a process pressure of about 2 torr and a process temperature of about 400° C.

7. The method of claim 1, wherein the silicon nitride film has a hydrogen content of about 13 atomic percent, a nitrogen content of about 37 atomic percent, and a silicon content of about 50 atomic percent.

8. The method of claim 1, wherein the silicon nitride film has a density of N—H bonds of about 4e21 bonds/cm³ and a density of Si—H bonds of about 3e22 bonds/cm³.

9. The method of claim 1, wherein the silicon nitride film has a density of hydrogen of about 3.6e22 atoms/cm³.

10. The method of claim 1, wherein the silicon nitride film has a ratio of Si—H bonds to N—H bonds of about 7:1.

11. The method of claim 1, wherein the silicon nitride film has a refractive index of about 2.7.

12. The method of claim 1, further comprising patterning the nitride film using a gas mixture comprising CF₄ and CHF₃.

13. A method, comprising:
providing a plasma-enhanced chemical vapor deposition (PECVD) reactor with a semiconductor substrate therein;
flowing a gas mixture consisting of silane and nitrogen into the PECVD reactor; and
forming a plasma in the PECVD reactor, whereby a silicon nitride film is deposited on the semiconductor substrate, the silicon nitride film having a stoichiometric composition of SiₓN_{y}H_{z}, wherein x>y>z.

14. The method of claim 13, wherein a flowrate of silane is about 100 sccm and a flowrate of nitrogen is about 4,500 sccm.

15. The method of claim 13, wherein a flowrate ratio of the silane to nitrogen is about 1:45.

16. The method of claim 13, wherein forming the plasma comprises applying a low frequency RF power of about 300 W to the plasma reactor, and maintaining a process pressure of about 2 torr and a process temperature of about 400° C.

17. The method of claim 13, wherein x is about 50, y is about 37, and z is about 13.

18. The method of claim 13, wherein the silicon nitride film has a density of N—H bonds of about 4e21 bonds/cm³, a density of Si—H bonds of about 3e22 bonds/cm³, and a density of hydrogen of about 3.6e22 atoms/cm³.

19. The method of claim 13, wherein the silicon nitride film has a ratio of Si—H bonds to N—H bonds of about 7:1.

20. The method of claim 13, wherein the silicon nitride film has a refractive index of about 2.7.
